(19) United States
(12) Patent Application Publication
(10) Pub. No.: US 2010/0096679 A1
(43) Pub. Date: Apr. 22, 2010

(54) FET, FERROELECTRIC MEMORY DEVICE, AND METHODS OF MANUFACTURING THE SAME

(75) Inventor: Byung-Eun PARK, Seoul (KR)

Correspondence Address: SEAN LIAM KELLEHER;Kelleher IP PLLC, 16 PECKSLIP RD, CARMEL, NY, 10512, US

(73) Assignee: University of Seoul Foundation of Industry- Academic Cooperation, Seoul (KR)

(21) Appl. No.: 12/525,077

(22) PCT Filed: Jun. 29, 2007
(86) PCT No.: PCT/KR07/02885

§ 371 Date: Jul. 29, 2009

(30) Foreign Application Priority Data
Dec. 29, 2006 (KR) 10-2006-0138741
Jun. 14, 2007 (KR) 10-2007-0058177

(51) Int. Cl. H01L 29/82; H01L 21/8242; H01L 27/105

(52) U.S. Cl. 257/295; 438/3; 438/197; 257/E27.081; 257/E21.646; 257/E29.323

(57) ABSTRACT

Disclosed herein are a field-effect transistor (FET), a ferroelectric memory device, and methods of manufacturing the same. The FET and the ferroelectric memory device in accordance with the present invention include: a substrate 1; source and drain regions 2 and 3 formed on the substrate; a channel layer 4 formed between the source and drain regions 2 and 3; and a ferroelectric layer 5 formed on the channel layer 4, the ferroelectric layer 5 being composed of a mixture of an inorganic ferroelectric material and an organic material. The ferroelectric layer 5 is formed in a manner that a mixed solution of an inorganic ferroelectric material and an organic material is applied onto the substrate and then subjected to annealing and etching processes.

### TECHNICAL FIELD

The present invention relates to a field-effect transistor (FET), a ferroelectric memory device, and methods of manufacturing the same.

### BACKGROUND ART

At present, extensive research aimed at realizing a transistor or a memory device using a ferroelectric material has continued to progress. FIG. 1 is a cross-sectional view showing a typical structure of a metal-ferroelectric-semiconductor (MFS) type memory device using a ferroelectric material.

As shown in FIG. 1, source and drain regions 2 and 3 are formed in predetermined areas of a silicon substrate 1, and a ferroelectric layer 5 is formed on a channel region 4 between the source and drain regions 2 and 3. In this case, the ferroelectric layer 5 comprises an inorganic material having ferroelectric properties such as PbZrₓTi₁₋ₓO₃ (PZT), SrBi₂Ta₂O₉ (SBT), (Bi,La)₄Ti₃O₁₂ (BLT), and the like. Moreover, a source electrode 6, a drain electrode 7 and a gate electrode 8 formed of a metal material, respectively, are arranged on the top of the source and drain regions 2 and 3 and the ferroelectric layer 5.

In the ferroelectric memory having the above-described structure, the ferroelectric layer 5 has polarization characteristics according to a voltage applied through the gate electrode 8, and a conductive channel is formed between the source region 2 and the drain region 3 by the polarization characteristics. As a result, a current flows between the source electrode 6 and the drain electrode 7.

Especially, in the above-described structure, even in the case where the voltage applied through the gate electrode 8 is cut off, the polarization characteristics of the ferroelectric layer 5 are continuously maintained. Accordingly, the above-described structure has attracted much attention since it can form a non-volatile memory only with one transistor (1T) even though a capacitor is not provided.

However, the ferroelectric memory having the above-described structure has the following problems. That is, when the ferroelectric layer 5 is directly formed on the silicon substrate 1 in the temperature range of 500 to 800° C. by a chemical vapor deposition (CVD) or sputtering method, for example, a transition layer of low quality is formed on the boundary between the ferroelectric layer 5 and the silicon substrate 1 by the high temperature, and chemical elements such as Pb and Bi in the ferroelectric layer 5 are diffused into the silicon substrate 1, thus making it difficult to form a ferroelectric layer 5 of high quality. As a result, there occurs a problem that the polarization characteristics of the ferroelectric layer 5 are deteriorated, that is, the data retention time of the ferroelectric memory becomes very short.

In view of the above problems, there has been recently proposed a so-called metal-ferroelectric-insulator-semiconductor (MFIS) structure, in which a buffer layer 20 formed mainly of an oxide is provided between the silicon substrate and the ferroelectric layer.

However, the above MFIS type ferroelectric memory has some problems in that it requires an additional process of forming the buffer layer 20, the data retention effect is not great, and the data retention time cannot exceed 30 days even in case of an excellent product manufactured in a laboratory.

### DISCLOSURE

### Technical Problem

Accordingly, the present invention has been made in an effort to solve the above-described problems. The present invention provides a field-effect transistor (FET) and a ferroelectric memory device having a simple structure and excellent data retention characteristics.

Moreover, the present invention provides methods of manufacturing the FET and the ferroelectric memory device.

### Technical Solution

In accordance with a first aspect of the present invention, there is provided a field-effect transistor comprising: source and drain regions formed in predetermined areas of a semiconductor substrate; a channel region formed between the source and drain regions; a ferroelectric layer formed on the channel region of the semiconductor substrate; and an electrode layer formed on the source and drain regions and the ferroelectric layer, wherein the ferroelectric layer is formed of a mixture of an inorganic ferroelectric material and an organic material.

In accordance with a second aspect of the present invention, there is provided a field-effect transistor comprising: source and drain regions formed in predetermined areas of a semiconductor substrate; a channel region formed between the source and drain regions; a ferroelectric layer formed on the channel region of the semiconductor substrate; and an electrode layer formed on the source and drain regions and the ferroelectric layer, wherein the ferroelectric layer is formed of a mixture of a solid solution of an inorganic ferroelectric material and an organic material.

The inorganic ferroelectric material may comprise at least one selected from the group consisting of a ferroelectric oxide, a ferroelectric fluoride, a ferroelectric semiconductor, and a mixture thereof.

The mixture may further comprise a silicide, a silicate or any other metal.

The organic material may be a polymer ferroelectric material.

The polymer ferroelectric material may be PVDF-TrFE.

In accordance with a third aspect of the present invention, there is provided a ferroelectric memory device comprising: source and drain regions formed in predetermined areas of a semiconductor substrate; a channel region formed between the source and drain regions; a ferroelectric layer formed on the channel region of the semiconductor substrate; and an electrode layer formed on the source and drain regions and the ferroelectric layer, wherein the ferroelectric layer is formed of a mixture of an inorganic ferroelectric material and an organic material.

In accordance with a fourth aspect of the present invention, there is provided a ferroelectric memory device comprising: source and drain regions formed in predetermined areas of a semiconductor substrate; a channel region formed between the source and drain regions; a ferroelectric layer formed on the channel region of the semiconductor substrate; and an electrode layer formed on the source and drain regions and the ferroelectric layer, wherein the ferroelectric layer is formed of a mixture of a solid solution of an inorganic ferroelectric material and an organic material.

The inorganic ferroelectric material may comprise at least one selected from the group consisting of a ferroelectric oxide, a ferroelectric fluoride, a ferroelectric semiconductor, and a mixture thereof.

The mixture may further comprise a silicide, a silicate or any other metal.

The organic material may be a polymer ferroelectric material.

The polymer ferroelectric material may comprise at least one selected from the group consisting of polyvinylidene fluoride (PVDF), PVDF polymer, PVDF copolymer, PVDF terpolymer and, further, odd-numbered nylon, cyano-polymer, and polymer or copolymer thereof.

The polymer ferroelectric material may be PVDF-TrFE.

In accordance with a fifth aspect of the present invention, there is provided a method of manufacturing a field-effect transistor, the method comprising: forming source and drain regions on a substrate; forming a channel region between the source and drain regions; preparing a mixed solution of an inorganic ferroelectric material and an organic material; applying the mixed solution on the substrate to form a ferroelectric layer; baking the ferroelectric layer; etching and removing the ferroelectric layer except for an area corresponding to the channel region; and forming a gate layer on the ferroelectric layer.

The mixed solution may comprise a PZT solution and a PVDF-TrFE solution.

In accordance with a sixth aspect of the present invention, there is provided a method of manufacturing a ferroelectric memory device, the method comprising: forming source and drain regions on a substrate; forming a channel region between the source and drain regions; preparing a mixed solution of an inorganic ferroelectric material and an organic material; applying the mixed solution on the substrate to form a ferroelectric layer; baking the ferroelectric layer; etching and removing the ferroelectric layer except for an area corresponding to the channel region; and forming a gate layer on the ferroelectric layer.

The inorganic ferroelectric material may comprise at least one selected from the group consisting of a ferroelectric oxide, a ferroelectric fluoride, a ferroelectric semiconductor, and a mixture thereof.

The inorganic ferroelectric material may be PZT.

The mixed solution may further comprise a silicide, a silicate or any other metal.

The organic material may be a polymer ferroelectric material.

The polymer ferroelectric material may comprise at least one selected from the group consisting of polyvinylidene fluoride (PVDF), PVDF polymer, PVDF copolymer, PVDF terpolymer and, further, odd-numbered nylon, cyano-polymer, and polymer or copolymer thereof.

The polymer ferroelectric material may be PVDF-TrFE.

The mixed solution may comprise a PZT solution and a PVDF-TrFE solution.

The PZT solution may be prepared by mixing a PZO solution and a PTO solution.

The PVDF-TrFE solution may be prepared by dissolving

PVDF-TrFE powder in at least one solvent selected from the group consisting of C₄H_{S}O (THF), C₄H₈O (MEK), C₃H₆O (acetone), C₃H₇NO (DMF), and C₂H₆OS (DMSO).

The ferroelectric layer may be formed by a spin coating method.

The ferroelectric layer may be formed by an ink-jet printing method.

The ferroelectric layer may be formed by a screen printing method.

The process of etching the ferroelectric layer may be performed by a buffered oxide etching (BOE) method.

The process of etching the ferroelectric layer may be performed by a two-step etching method using BOE and gold etchant.

The process of etching the ferroelectric layer may be performed by a reactive ion etching (RIE) method.

The baking temperature may be below 200° C.

### DESCRIPTION OF DRAWINGS

FIG. 1 is a cross-sectional view showing a typical structure of a metal-ferroelectric-semiconductor (MFS) type memory device;

FIGS. 2 to 6 are graphs showing capacitance-voltage characteristics of ferroelectric materials applied to the present invention;

FIG. 7 is a graph showing the change in capacitance of the ferroelectric layer formed of a ferroelectric material in accordance with the present invention with the passage of time.

### MODE FOR INVENTION

Hereinafter, preferred embodiments in accordance with the present invention will be described with reference to the accompanying drawings. The preferred embodiments are provided so that those skilled in the art can sufficiently understand the present invention, but can be modified in various forms and the scope of the present invention is not limited to the preferred embodiments.

First, the basic concept of the present invention will be described below.

At present, there are known various materials showing ferroelectric characteristics. Such materials are broadly classified into inorganic materials and organic materials. The inorganic ferroelectric materials include ferroelectric oxides, ferroelectric fluorides such as BaMgF₄ (BMF), and ferroelectric semiconductors. The organic ferroelectric materials include polymer ferroelectric materials and the like.

The ferroelectric oxides include perovskite ferroelectric materials such as PbZrₓTi₁₋ₓO₃ (PZT), BaTiO₃ and PBTiO₃, pseudo-ilmenite ferroelectric materials such as LiNbO₃ and LiTaO₃, tungsten-bronze (TB) ferroelectric materials such as PbNb₃O₆ and Ba₂NaNb₅O₁₅, ferroelectric materials having a bismuth layer structure such as SrBi₂Ta₂O₉ (SBT), (Bi,La)₄Ti₃O₁₂ (BLT) and Bi₄Ti₃O₁₂, pyrochlore ferroelectric materials such as La₂Ti₂O₇, and ferroelectric materials such as RMnO₃, Pb₅Ge₃O₁₁ (PGO) and BiFeO₃ (BFO) including a rare earth element (R) such as Y, Er, Ho, Tm, Yb and Lu.

Moreover, the ferroelectric semiconductors include 2-6 compounds such as CdZnTe, CdZnS, CdZnSe, CdMnS, CdFeS, CdMnSe and CdFeSe.

Furthermore, the polymer ferroelectric materials include polyvinylidene fluoride (PVDF), PVDF polymer, PVDF copolymer, PVDF terpolymer and, further, odd-numbered nylon, cyano-polymer, and polymer or copolymer thereof.

In general, the inorganic ferroelectric materials including the ferroelectric oxides, the ferroelectric fluorides and the ferroelectric semiconductors have dielectric constants greater than those of the organic ferroelectric materials. Accordingly, the generally proposed ferroelectric field-effect transistor (FET) or ferroelectric memory device employs the inorganic ferroelectric materials for forming the ferroelectric layer.

However, the above-described inorganic ferroelectric materials require a high temperature treatment above 500° C., for example, to be formed on a substrate. In the case where an inorganic ferroelectric layer is formed through the high temperature treatment on the substrate, a transition layer of low quality is formed on the boundary between the ferroelectric layer and a silicon substrate due to the high temperature, and chemical elements such as Pb and Bi in the ferroelectric material are diffused into the silicon substrate, thus shortening the data retention time of the ferroelectric memory.

According to the study by the present inventor, the inorganic ferroelectric materials are formed at higher temperatures, while their dielectric constants are high. However, the organic materials including the organic ferroelectric materials are formed at lower temperatures, while their dielectric constants are relatively low. Accordingly, when mixing the inorganic ferroelectric material with the organic material or the organic ferroelectric material, it is possible to obtain a ferroelectric material having a dielectric constant above a predetermined value and formed at a much lower temperature.

In this case, methods of forming mixed solutions of the inorganic ferroelectric material and the organic material or the organic ferroelectric material are as follows:

1. Mixing an inorganic powder with an organic powder and dissolving the mixed powders in a solvent to form a mixed solution;

2. Dissolving an organic powder in an inorganic solution to form a mixed solution;

3. Dissolving an inorganic powder in an organic solution to form a mixed solution; and

4. Mixing an organic solution with an inorganic solution to form a mixed solution.

Moreover, the inorganic ferroelectric material and the organic material may be mixed with each other as follows:

1. Mixing an inorganic ferroelectric material with an organic material;

2. Mixing an inorganic ferroelectric material with an organic ferroelectric material;

3. Mixing a solid solution of an inorganic ferroelectric material with an organic material;

4. Mixing a solid solution of an inorganic ferroelectric material with an organic ferroelectric material; and

5. Mixing the aforementioned mixture with a silicide, a silicate or another metal.

Of course, the above mixing methods are not limited to specific methods and any method that can appropriately mix the inorganic material with the organic material may be employed.

The organic materials mixed with the inorganic ferroelectric material include, a monomer, an oligomer, a polymer, and a copolymer. Preferably, an organic material having a high dielectric constant may be used.

The organic materials having a high dielectric constant include polyvinylpyrrolidone (PVP), polycarbonate (PC), polyvinyl chloride (PVC), polystyrene (PS), epoxy, polymethylmethacrylate (PMMA), polyimide (PT), polyethylene (PE), polyvinyl alcohol (PVA), polyhexamethylene adipamide (nylon 66), polyetherketoneketone (PEKK), and the like.

Moreover, the organic materials include a nonpolar organic material, such as fluorinated para-xylene, fluoropolyarylether, fluorinated polyimide, polystyrene, poly(α-methyl styrene), poly(α-vinylnaphthalene), poly(vinyltoluene), polyethylene, cis-polybutadiene, polypropylene, polyisoprene, poly(4-methyl-1-pentene), poly(tetrafluoroethylene), poly(chlorotrifluoroethylene), poly(2-methyl-1,3-butadiene), poly(p-xylylene), poly(α-α-α′-α′-tetrafluoro-p-xylylene), poly[1,1-(2-methyl propane)bis(4-phenyl)carbonate], poly(cyclohexyl methacrylate), poly(chlorostyrene), poly(2,6-dimethyl-1,4-phenylene ether), polyisobutylene, poly(vinyl cyclohexane), poly(arylene ether), and polyphenylene, or copolymers having a low dielectric constant, such as poly(ethylene/tetrafluoroethylene), poly(ethylene/chlorotrifluoroethylene), fluorinated ethylene/propylene copolymer, polystyrene-co-α-methyl styrene, ethylene/ethyl acrylate copolymer, poly(styrene/10% butadiene), poly(styrene/15% butadiene), poly(styrene/2,4-dimethylstyrene), Cytop, Teflon AF, and polypropylene-co-1-butene.

Other organic semi-conducting materials that can be used in this invention include soluble compounds and soluble derivatives of compounds of the following list: conjugated hydrocarbon polymers such as polyacene, polyphenylene, poly(phenylene vinylene), polyfluorene including oligomers of those conjugated hydrocarbon polymers; condensed aromatic hydrocarbons such as anthracene, tetracene, chrysene, pentacene, pyrene, perylene, coronene; oligomeric para substituted phenylenes such as p-quaterphenyl (p-4P), p-quinquephenyl (p-5P), p-sexiphenyl (p-6P); conjugated heterocyclic polymers such as poly(3-substituted thiophene), poly(3,4-bisubstituted thiophene), polybenzothiophene, polyisothianapthene, poly(N-substituted pyrrole), poly(3-substituted pyrrole), poly(3,4-bisubstituted pyrrole), polyfuran, polypyridine, poly-1,3,4-oxadiazoles, polyisothianaphthene, poly(N-substituted aniline), poly(2-substituted aniline), poly(3-substituted aniline), poly(2,3-bisubstituted aniline), polyazulene, polypyrene; pyrazoline compounds; polyselenophene; polybenzofuran; polyindole; polypyridazine; benzidine compounds; stilbene compounds; triazines; substituted metallo- or metal-free porphines, phthalocyanines, fluorophthalocyanines, naphthalocyanines, or fluoronaphthalocyanines; C₆₀ and C₇₀ fullerenes; N,N′-dialkyl, substituted dialkyl, diaryl or substituted diaryl-1,4,5,8-naphthalenetetracarboxylic diimide; N,N′-dialkyl, substituted dialkyl, diaryl or substituted diaryl 3,4,9,10-perylenetetracarboxylicdiimide; bathophenanthroline; diphenoquinones; 1,3,4-oxadiazoles; 11,11,12,12-tetracyanonaptho-2,6-quinodimethane; α,α′-bis(dithieno[3,2-b2′,3′-d]thiophene); 2,8-dialkyl, substituted dialkyl, diaryl or substituted diaryl anthradithiophene; and 2,2′-bibenzo[1,2-b:4,5-b′]dithiophene.

It is possible to appropriately set the mixture ratio of the inorganic material and the organic material. If the mixture ratio of the inorganic ferroelectric material is increased, the formation temperature is increased while the dielectric constant of the mixture is increased, whereas if the mixture ratio of the inorganic ferroelectric material is decreased, the formation temperature is lowered while the dielectric constant of the mixture is reduced.

The ferroelectric materials employed in the present invention have the following characteristics:

1. Since the ferroelectric layer is formed using a mixed solution of an inorganic material and an organic material, it is possible to easily form the ferroelectric layer by an ink-jet printing, spin coating or screen printing method; and

2. Since the formation temperature of the ferroelectric layer is lowered to below about 200° C., it is possible to form the ferroelectric layer having excellent data retention characteristics on the silicon substrate; and

3. Since the formation temperature of the ferroelectric layer is lowered, it is possible to form the field-effect transistor or ferroelectric memory device on various kinds of substrates such as an organic material or paper instead of the existing silicon substrate.

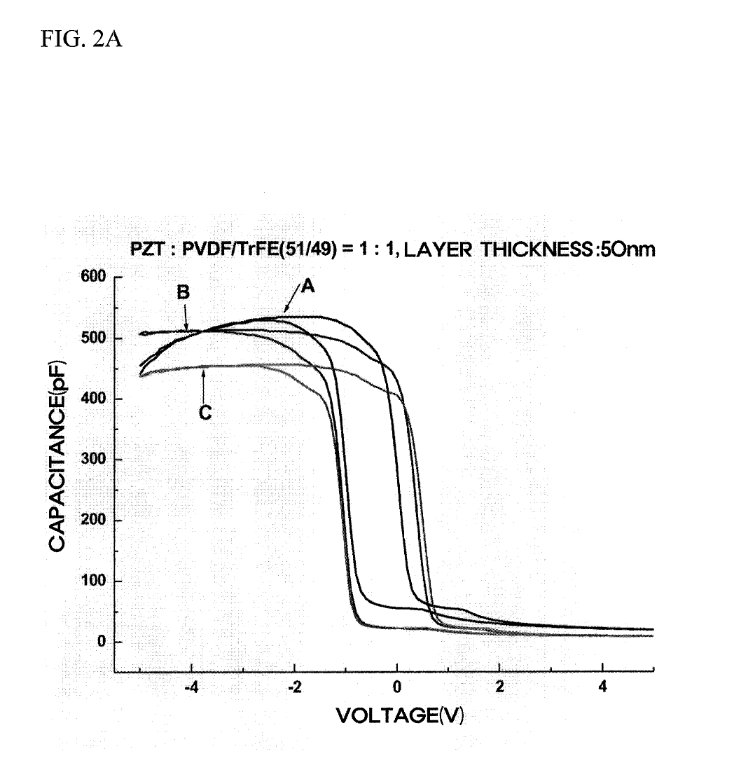

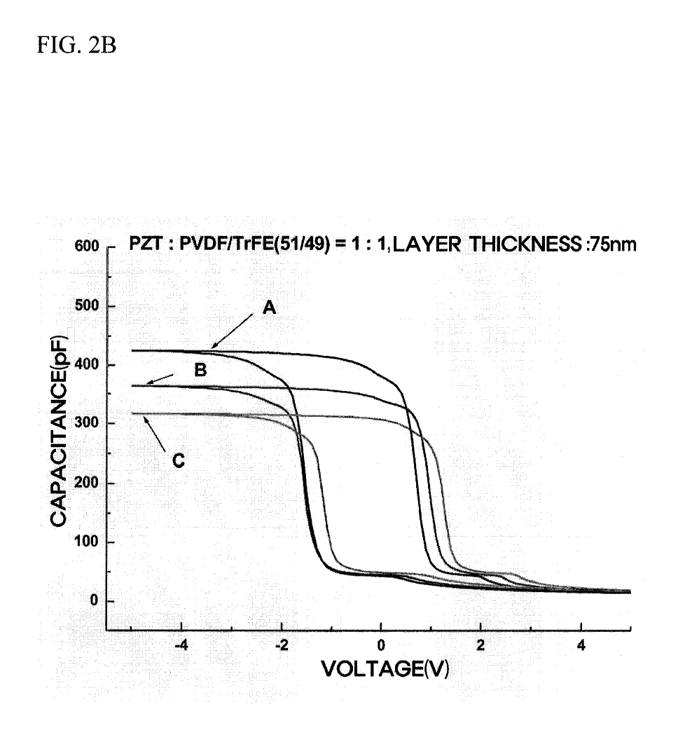

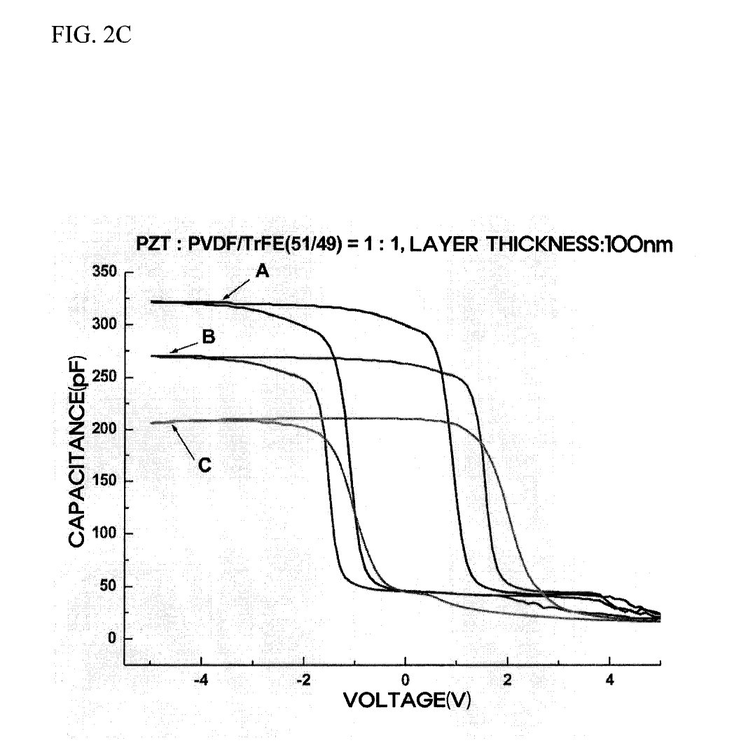

Meanwhile, FIGS. 2 to 6 are graphs showing polarization characteristics of ferroelectric layers formed of an inorganic ferroelectric material and an organic ferroelectric material such as PbZrₓTi₁₋ₓO₃ (PZT) and PVDF-TrFE mixed in predetermined ratios.

Here, the ferroelectric layer was formed in such a manner that a PZT solution and a PVDF-TrFE solution were mixed in a predetermined ratio to form a mixed solution, the mixed solution was coated on a silicon wafer by a spin coating method, and the resulting silicon wafer was heated in the temperature range of 150 to 200° C. on a hot plate for a predetermined period of time.

Moreover, the PZT solution was prepared by mixing a PZO solution and a PTO solution, in which the PZO solution was formed by mixing a zirconium propoxide solution with a mixed solution of a 2-methoxyethanol solution and a lead acetate trihydrate solution and the PTO solution was formed by mixing a titanium isopropoxide solution with the mixed solution of the 2-methoxyethanol solution and the lead acetate trihydrate solution.

The PVDF-TrFE solution was prepared by dissolving PVDF-TrFE powder in a solvent such as C₄H_{S}O (THF), C₄H₈O (MEK), C₃H₆O (acetone), C₃H₇NO (DMF), and C₂H₆OS (DMSO).

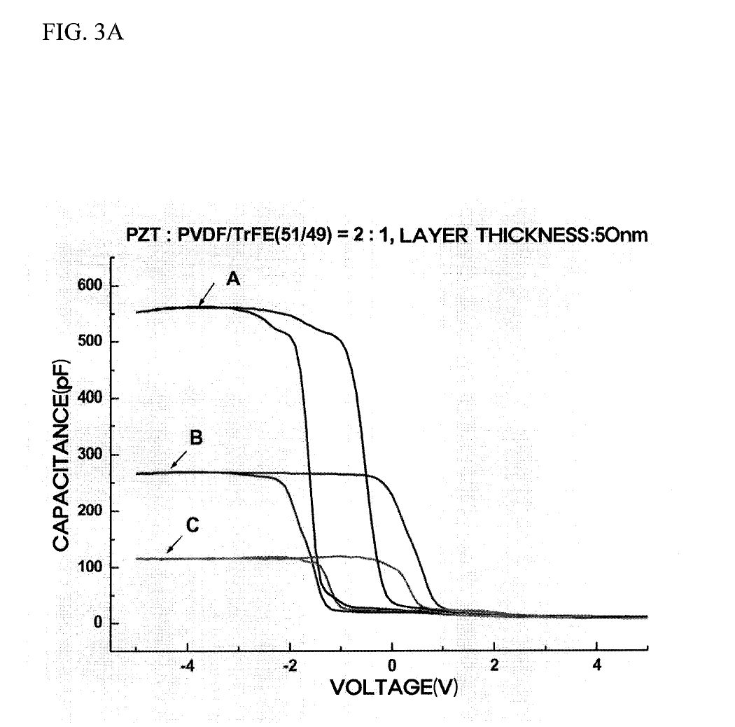

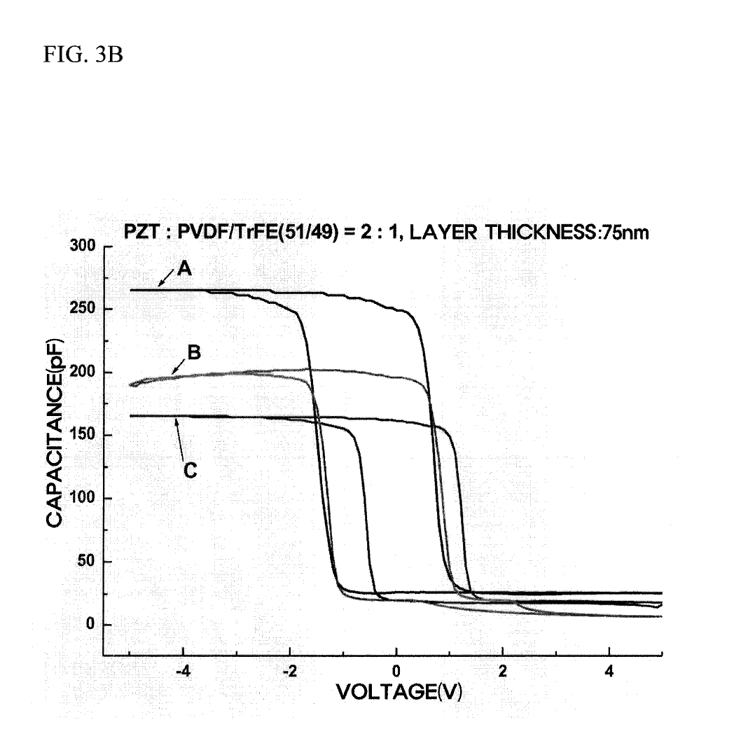

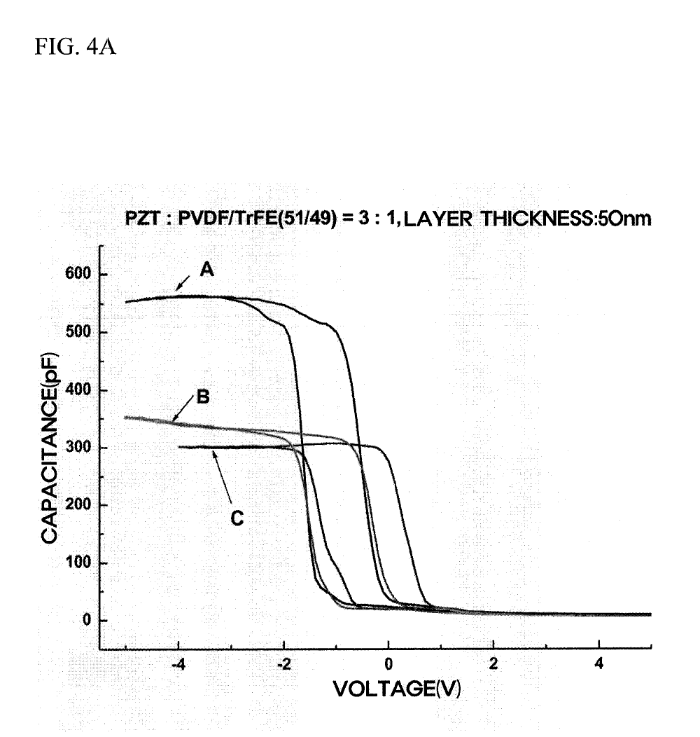

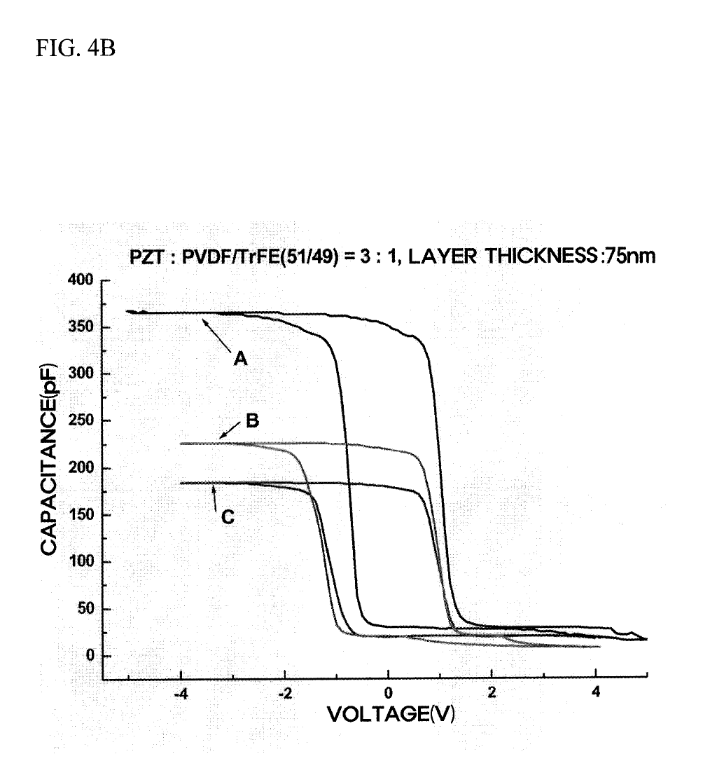

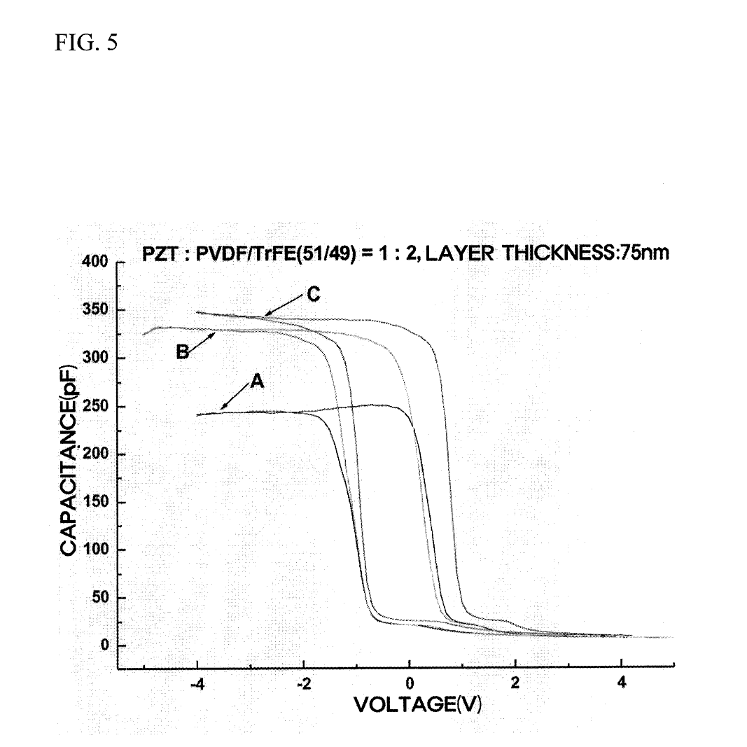

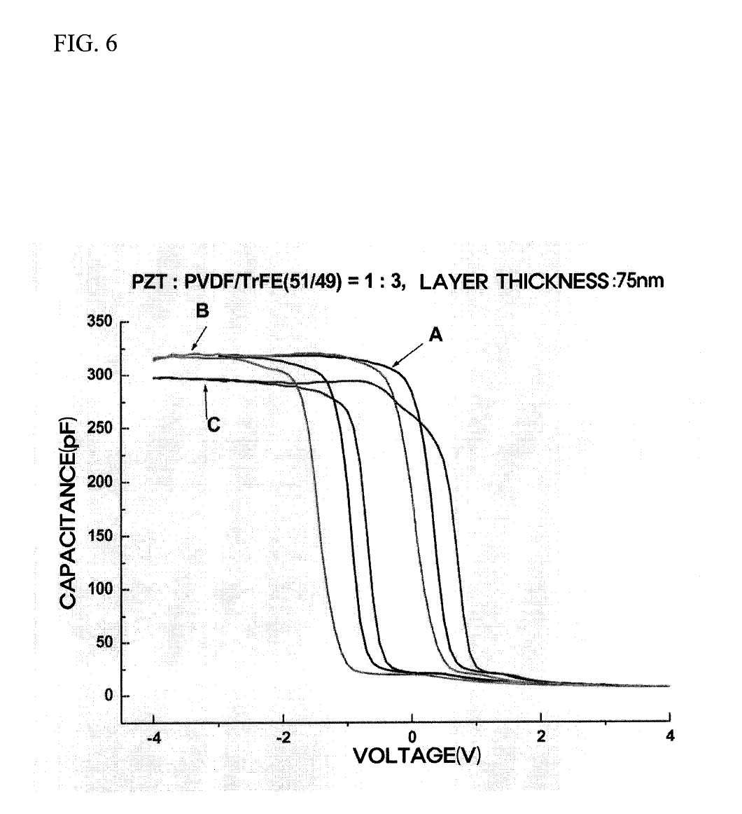

FIG. 2 shows the polarization characteristics in which the mixed ratio of the PZT and PVDF-TrFE was 1:1, FIG. 3 shows the polarization characteristics in which the mixed ratio of the PZT and PVDF-TrFE was 2:1, FIG. 4 shows the polarization characteristics in which the mixed ratio of the PZT and PVDF-TrFE was 3:1, FIG. 5 shows the polarization characteristics in which the mixed ratio of the PZT and PVDF-TrFE was 1:2, and FIG. 6 shows the polarization characteristics in which the mixed ratio of the PZT and PVDF-TrFE was 1:3.

In FIGS. 2A, 3A and 4A, the thickness of the ferroelectric layer was 50 nm; in FIGS. 2B, 3B, 4B, 5 and 6, the thickness of the ferroelectric layer was 75 nm; and in FIG. 2C, the thickness of the ferroelectric layer was 100 nm.

Moreover, in FIGS. 2 to 6, the characteristic curves represented as A show the polarization characteristics in which the formation temperature of the ferroelectric layer was 190° C., the characteristic curves represented as B show the polarization characteristics in which the formation temperature of the ferroelectric layer was 170° C., and the characteristic curves represented as C show the polarization characteristics in which the formation temperature of the ferroelectric layer was 150° C.

Referring to FIGS. 2 to 6, in the case where the mixed ratio of the PZT and PVDF-TrFE was 1:1 or in the case where the mixed ratio of the PVDF-TrFE was greater than that of the PZT, generally good polarization characteristics were shown in the temperature range of 150 to 190° C., and the higher the mixed ratio of the PZT was, the better the polarization characteristics were shown at higher temperatures.

Moreover, the higher the thickness of the ferroelectric layer, the lower the polarization value, i.e., the capacitance value, whereas the greater the size of the memory window.

Especially, it was remarkable that, even in the case where the mixed ratio of the PZT and PVDF-TrFE was changed or in the case where the formation temperature was set to a temperature below about 200° C., excellent hysteresis characteristics were shown.

As described above, since the formation temperature of the ferroelectric layer formed of the conventional inorganic ferroelectric material is higher than that of the ferroelectric layer formed in accordance with the present invention, various problems occur when forming the ferroelectric layer on the silicon substrate. Contrarily, when the mixture of the inorganic ferroelectric material and the organic material is used, it is possible to form the ferroelectric layer at a low temperature of below 200° C. and excellent hysteresis characteristics are shown in a voltage range of −5 to 5 V. Accordingly, the ferroelectric material in accordance with the present invention can be effective used as the material of the ferroelectric field-effect transistor or ferroelectric memory.

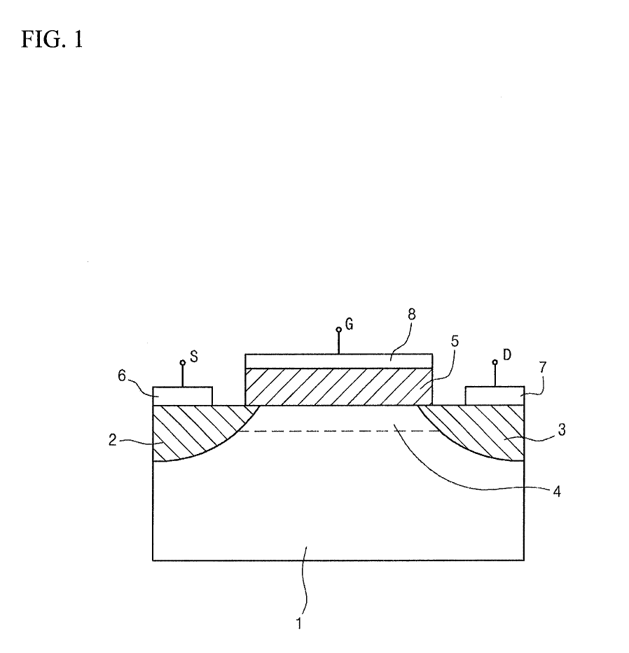

Referring back to FIG. 1, in the case where the MFS type FET or the ferroelectric memory device is formed of a ferroelectric material in accordance with the present invention, source and drain regions 2 and 3 and a channel region 4 are formed in predetermined areas of a silicon substrate 1 by the same method as the conventional method.

Next, a ferroelectric solution in accordance with the present invention is coated on the above structure by a spin coating, ink-jet printing, or screen printing method, and the resulting structure is baked at a low temperature below 200° C., for example, thus forming a ferroelectric layer. Here, the ferroelectric material may include a mixture of an inorganic ferroelectric material and an organic material, a mixture of an inorganic ferroelectric material and an organic ferroelectric material, a mixture of a solid solution of an inorganic ferroelectric material and an organic material, a mixture of a solid solution of an inorganic ferroelectric material and an organic ferroelectric material, and a mixture further comprising a silicide, a silicate or any other metal.

Subsequently, the ferroelectric layer except for the area corresponding to the channel region is removed by a buffered oxide etching (BOE), two-step etching using BOE and gold etchant, or reactive ion etching (RIE) method, thus forming a ferroelectric layer 5.

Then, a source electrode 6, a drain electrode 7 and a gate electrode 8 are formed of a metal material, respectively, on the top of the source and drain regions 2 and 3 and the ferroelectric layer 5, like the general one.

In the FET and the ferroelectric memory device in accordance with the present invention, the ferroelectric layer 5 is formed at a lower temperature below 200° C. Accordingly, it is possible to solve the problems that a transition layer of low quality is formed on the boundary between the ferroelectric layer and the silicon substrate due to the high temperature and chemical elements such as Pb and Bi in the ferroelectric material are diffused into the silicon substrate during the formation of the ferroelectric layer on the silicon substrate. That is, it is possible to form a ferroelectric layer of good quality on the silicon substrate. Accordingly, it is possible to significantly increase the data retention time of the ferroelectric memory device.

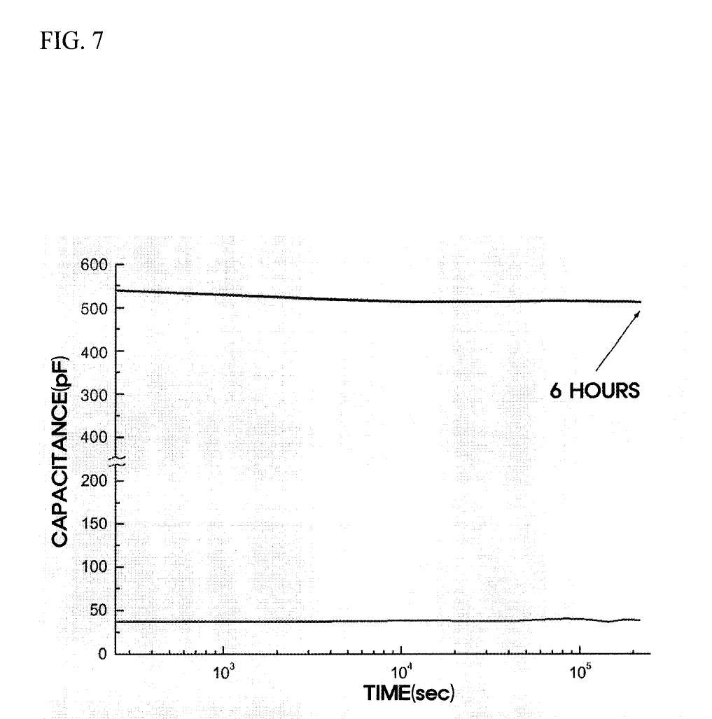

FIG. 7 is a graph showing the change in capacitance of the ferroelectric layer formed of the ferroelectric material in accordance with the present invention with the passage of time.

As can be seen from FIG. 7, there is no change in the capacitance value of the ferroelectric material in accordance with the present invention with the passage of time. Accordingly, the ferroelectric material in accordance with the present invention can be effectively used as a material for a non-volatile memory device.

The invention has been described in detail with reference to preferred embodiments thereof. However, it will be appreciated by those skilled in the art that changes may be made in these embodiments without departing from the principles and spirit of the invention, the scope of which is defined in the appended claims and their equivalents.

### INDUSTRIAL APPLICABILITY

As described above, according to the present invention, it is possible to realize a field-effect transistor (FET) and a ferroelectric memory device having excellent ferroelectric characteristics and capable of being formed at a low temperature below 200° C.

1. A field-effect transistor comprising:
source and drain regions formed in predetermined areas of a semiconductor substrate;
a channel region formed between the source and drain regions;
a ferroelectric layer formed on the channel region of the semiconductor substrate; and
an electrode layer formed on the source and drain regions and the ferroelectric layer,
wherein the ferroelectric layer is formed of a mixture of an inorganic ferroelectric material and an organic material.

2. The field-effect transistor of claim 1, wherein the inorganic ferroelectric material comprises at least one selected from the group consisting of a ferroelectric oxide, a ferroelectric fluoride, a ferroelectric semiconductor, and a mixture thereof.

3. The field-effect transistor of claim 1, wherein the mixture further comprises a silicide, a silicate or any other metal.

4. The field-effect transistor of claim 1, wherein the organic material is a polymer ferroelectric material.

5. The field-effect transistor of claim 1, wherein the polymer ferroelectric material is PVDF-TrFE.

6. A field-effect transistor comprising:
source and drain regions formed in predetermined areas of a semiconductor substrate;
a channel region formed between the source and drain regions;
a ferroelectric layer formed on the channel region of the semiconductor substrate; and
an electrode layer formed on the source and drain regions and the ferroelectric layer,
wherein the ferroelectric layer is formed of a mixture of a solid solution of an inorganic ferroelectric material and an organic material.

7. The field-effect transistor of claim 6, wherein the organic material is an organic ferroelectric material.

8. A ferroelectric memory device comprising:
source and drain regions formed in predetermined areas of a semiconductor substrate;
a channel region formed between the source and drain regions;
a ferroelectric layer formed on the channel region of the semiconductor substrate; and
an electrode layer formed on the source and drain regions and the ferroelectric layer,
wherein the ferroelectric layer is formed of a mixture of an inorganic ferroelectric material and an organic material.

9. The ferroelectric memory device of claim 8, wherein the inorganic ferroelectric material comprises at least one selected from the group consisting of a ferroelectric oxide, a ferroelectric fluoride, a ferroelectric semiconductor, and a mixture thereof.

10. The ferroelectric memory device of claim 8, wherein the mixture further comprises a silicide, a silicate or any other metal.

11. The ferroelectric memory device of claim 8, wherein the organic material is a polymer ferroelectric material.

12. The ferroelectric memory device of claim 11, wherein the polymer ferroelectric material comprises at least one selected from the group consisting of polyvinylidene fluoride (PVDF), PVDF polymer, PVDF copolymer, PVDF terpolymer and, further, odd-numbered nylon, cyano-polymer, and polymer or copolymer thereof.

13. The ferroelectric memory device of claim 11, wherein the polymer ferroelectric material is PVDF-TrFE.

14. A ferroelectric memory device comprising:
source and drain regions formed in predetermined areas of a semiconductor substrate;
a channel region formed between the source and drain regions;
a ferroelectric layer formed on the channel region of the semiconductor substrate; and
an electrode layer formed on the source and drain regions and the ferroelectric layer,
wherein the ferroelectric layer is formed of a mixture of a solid solution of an inorganic ferroelectric material and an organic material.

15. The ferroelectric memory device of claim 14, wherein the organic material is an organic ferroelectric material.

16. A method of manufacturing a field-effect transistor, the method comprising:
forming source and drain regions on a substrate;
forming a channel region between the source and drain regions;
preparing a mixed solution of an inorganic ferroelectric material and an organic material;
applying the mixed solution on the substrate to form a ferroelectric layer;
baking the ferroelectric layer;
etching and removing the ferroelectric layer except for an area corresponding to the channel region; and
forming a gate layer on the ferroelectric layer.

17. The method of claim 16, wherein the mixed solution comprises a PZT solution and a PVDF-TrFE solution.

18. A method of manufacturing a ferroelectric memory device, the method comprising:
forming source and drain regions on a substrate;
forming a channel region between the source and drain regions;
preparing a mixed solution of an inorganic ferroelectric material and an organic material;
applying the mixed solution on the substrate to form a ferroelectric layer;
baking the ferroelectric layer;
etching and removing the ferroelectric layer except for an area corresponding to the channel region; and
forming a gate layer on the ferroelectric layer.

19. The method of claim 18, wherein the inorganic ferroelectric material comprises at least one selected from the group consisting of a ferroelectric oxide, a ferroelectric fluoride, a ferroelectric semiconductor, and a mixture thereof.

20. The method of claim 18, wherein the inorganic ferroelectric material is PZT.

21. The method of claim 18, wherein the mixed solution further comprises a silicide, a silicate or any other metal.

22. The method of claim 18, wherein the organic material is a polymer ferroelectric material.

23. The method of claim 22, wherein the polymer ferroelectric material comprises at least one selected from the group consisting of polyvinylidene fluoride (PVDF), PVDF polymer, PVDF copolymer, PVDF terpolymer and, further, odd-numbered nylon, cyano-polymer, and polymer or copolymer thereof.

24. The method of claim 22, wherein the polymer ferroelectric material is PVDF-TrFE.

25. The method of claim 18, wherein the mixed solution comprises a PZT solution and a PVDF-TrFE solution.

26. The method of claim 25, wherein the PZT solution is prepared by mixing a PZO solution and a PTO solution.

27. The method of claim 25, wherein the PVDF-TrFE solution is prepared by dissolving PVDF-TrFE powder in at least one solvent selected from the group consisting of C₄H_{S}O (THF), C₄H₈O (MEK), C₃H₆O (acetone), C₃H₇NO (DMF), and C₂H₆OS (DMSO).

28. The method of claim 18, wherein the ferroelectric layer is formed by a spin coating method.

29. The method of claim 18, wherein the ferroelectric layer is formed by an ink-jet printing method.

30. The method of claim 18, wherein the ferroelectric layer is formed by a screen printing method.

31. The method of claim 18, wherein etching the ferroelectric layer is performed by a buffered oxide etching (BOE) method.

32. The method of claim 18, wherein etching the ferroelectric layer is performed by a two-step etching method using BOE and gold etchant.

33. The method of claim 18, wherein etching the ferroelectric layer is performed by a reactive ion etching (RIE) method.

34. The method of claim 18, wherein the baking temperature is below 200° C.
